(19) United States
(12) Patent Application Publication
(10) Pub. No.: US 2023/0189505 A1
(43) Pub. Date: Jun. 15, 2023

(54) SEMICONDUCTOR STRUCTURE AND METHOD FOR PREPARING SEMICONDUCTOR STRUCTURE

(71) Applicant: CHANGXIN MEMORY TECHNOLOGIES, INC., Hefei City (CN)

(72) Inventor: Feng WU, Hefei (CN)

(21) Appl. No.: 18/167,138

(22) Filed: Feb. 10, 2023

Related U.S. Application Data
(63) Continuation of application No. PCT/CN2022/073715, filed on Jan. 25, 2022.

(30) Foreign Application Priority Data
Aug. 12, 2021 (CN) 202110926800.6

(51) Int. Cl. H10B 12/00

(52) U.S. Cl. CPC H10B 12/315; H10B 12/482; H10B 12/033

(57) ABSTRACT

A semiconductor structure includes a plurality of bit line stack structures, a plurality of storage contact structures and a plurality of capacitor structures. The plurality of bit line stack structures are disposed on a substrate. Each of the plurality of storage contact structures is disposed between a pair of bit line stack structures of the plurality of bit line stack structures, and a top surface of each of the plurality of storage contact structures is lower than a top surface of each of the plurality of bit line stack structures. A part of a bottom surface of a lower electrode of each of the plurality of capacitor structures is supported on the top surface of a respective one of the plurality of storage contact structures, and another part of the bottom surface is supported on the top surface of a respective one of the plurality of bit line stack structures.

### CROSS-REFERENCE TO RELATED APPLICATIONS

This application is a continuation application of International Patent Application No. PCT/CN2022/073715, filed on Jan. 25, 2022, which claims priority to Chinese Patent Application No. 202110926800.6, filed on Aug. 12, 2021. The disclosures of International Patent Application No. PCT/CN2022/073715 and Chinese Patent Application No. 202110926800.6 are hereby incorporated by reference in their entireties.

### BACKGROUND

With the development of semiconductor technology, the dimension of a semiconductor device is gradually reduced, and the reduction of the thickness of the semiconductor device has become the main research and development direction of the semiconductor device in the future.

In order to store charge in the semiconductor device, a sufficiently high capacitance value needs to be maintained. Generally, in order to increase or maintain the capacity of a capacitor, the height of a lower electrode is increased or the thickness of the lower electrode is decreased to enlarge the contact area between the lower electrode and a capacitance dielectric layer. Decreasing the thickness of the lower electrode easily causes the lower electrode to collapse, and increasing the height of the lower electrode results in an increase in the thickness of the semiconductor device.

### SUMMARY

Embodiments of the disclosure relate to, but are not limited to a semiconductor structure and a method for preparing a semiconductor structure.

The embodiments of the disclosure provide a semiconductor structure, which includes a plurality of bit line stack structures, a plurality of storage contact structures and a plurality of capacitor structures.

The plurality of bit line stack structures are disposed on a substrate.

Each of the plurality of storage contact structures is disposed between a pair of bit line stack structures of the plurality of bit line stack structures, and a top surface of each of the plurality of storage contact structures is lower than a top surface of each of the plurality of bit line stack structures.

A part of a bottom surface of a lower electrode of each of the plurality of capacitor structures is supported on the top surface of a respective one of the plurality of storage contact structures, and another part of the bottom surface of the lower electrode is supported on the top surface of a respective one of the plurality of bit line stack structures.

The embodiments of the disclosure further provide a method for preparing a semiconductor structure, which includes the following operations.

A plurality of bit line stack structures are formed on a substrate.

A storage contact structure is formed between a pair of bit line stack structures of the plurality of bit line stack structures, where a top surface of the storage contact structure is lower than a top surface of each of the plurality of bit line stack structures.

A lower electrode is formed, where a part of a bottom surface of the lower electrode is supported on the top surface of the storage contact structure, and another part of the bottom surface of the lower electrode is supported on the top surface of a respective one of the pair of bit line stack structures.

### BRIEF DESCRIPTION OF THE DRAWINGS

Further details, features and advantages of the disclosure are disclosed in the following description of exemplary embodiments, taken in conjunction with the accompanying drawings. In the drawings:

FIG. 1 is a schematic cross-sectional view of a semiconductor structure in the related art.

FIG. 2 is a top view of the semiconductor structure as shown in FIG. 1.

FIG. 3 illustrates a schematic cross-sectional view of a semiconductor structure according to an exemplary embodiment of the disclosure.

FIG. 4 illustrates a top view of the semiconductor structure as shown in FIG. 3.

FIG. 5 illustrates a flowchart of a method for preparing a semiconductor structure according to an embodiment of the disclosure.

FIG. 6 illustrates a flowchart of a method for preparing a contact pad according to an embodiment of the disclosure.

FIG. 7 illustrates a flowchart of a method for preparing a lower electrode according to an embodiment of the disclosure.

FIG. 8 illustrates a schematic diagram when S201 is performed according to a method for preparing a contact pad as shown in FIG. 6.

FIG. 9 illustrates a schematic diagram when S202 is performed according to a method for preparing a contact pad as shown in FIG. 6.

FIG. 10 illustrates a schematic diagram when S301 is performed according to a method for preparing a lower electrode as shown in FIG. 7.

FIG. 11 illustrates a schematic diagram when S302 is performed according to a method for preparing a lower electrode as shown in FIG. 7.

FIG. 12 illustrates a schematic diagram when S303 is performed according to a method for preparing a lower electrode as shown in FIG. 7.

FIG. 13 illustrates a schematic diagram when S304 is performed according to a method for preparing a lower electrode as shown in FIG. 7.

The reference numerals are listed as follows:

Substrate, 1; Word line, 11;

Support structure, 2; Storage contact structure, 21; Storage node plug, 211; contact pad, 212; Bit line stack structure, 22; Bit line insulating layer, 221; Bit line, 222; Bit line contact plug, 223;

Lower electrode, 33; First side, 331; Second side, 332; Third side, 333; Fourth side, 334; Fifth side, 335; Sixth side, 336;

Pad adhesion layer, 4;

Bit line adhesion layer, 5;

Pad oxide layer, 6;

Sacrificial layer, 7;

Capacitor hole, 8;

First storage contact structure, 91; First bit line stack structure, 92; First contact pad, 93; First lower electrode, 94; First capacitance dielectric layer, 95; First upper electrode, 96; First substrate, 97.

### DETAILED DESCRIPTION

The embodiments of the disclosure will be described in detail below with reference to the drawings. Although some embodiments of the disclosure are shown in the drawings, it should be understood that the disclosure may be implemented in various forms and should not be construed as limited to the embodiments set forth herein, but rather, these embodiments are provided for a more thorough and complete understanding of the disclosure. It is to be understood that the drawings and embodiments of the disclosure are for exemplary purpose only and are not intended to limit the scope of protection of the disclosure.

It is to be understood that various operations in the implementation mode of the method of the disclosure may be performed in a different order, and/or in parallel. In addition, the implementation mode of the method may include additional operations and/or omit performing illustrated operations. The scope of the disclosure is not limited herein.

As used herein, the term “include” and its variants are open-ended, that is, “including, but not limited to”. The term “based on” is “based at least in part on”. The term “one embodiment” means “at least one embodiment”; the term “another embodiment” means “at least one other embodiment”; and the term “some embodiments” means “at least some embodiments”. Related definitions for other terms will be given in the following description. It is to be noted that the concepts of “first”, “second”, and the like referred to in the disclosure are only used to distinguish different elements, but not to limit functions or interdependencies of these elements.

It is to be noted that the modifications to “one” or “a plurality of” in the disclosure are illustrative and not restrictive, and those skilled in the art should understood that they should be understood as “one or a plurality of”, unless otherwise definitely specified in the context.

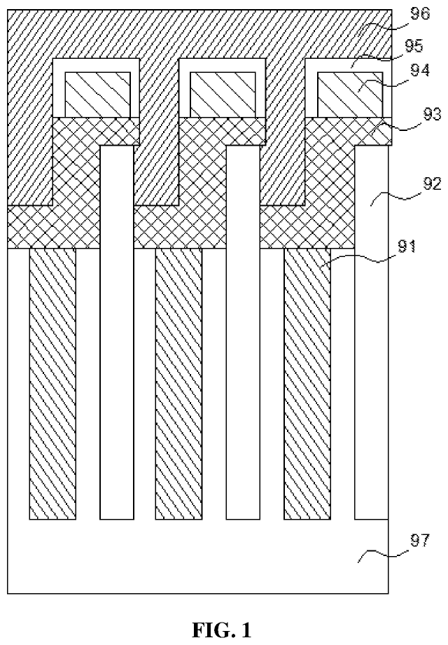

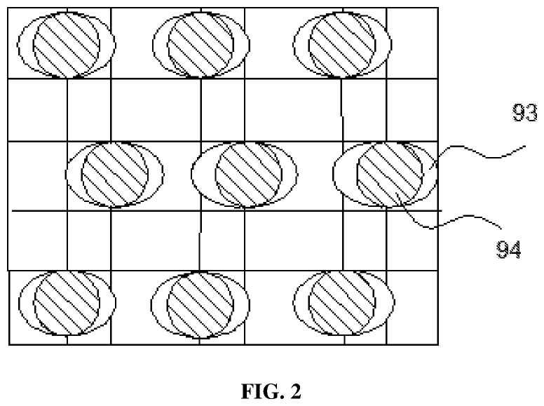

FIG. 1 is a schematic cross-sectional view of a semiconductor structure in the related art. As shown in FIG. 1, the semiconductor structure includes a first substrate 97, a first storage contact structure 91, a first bit line stack structure 92, a first contact pad 93, a first lower electrode 94, a first capacitance dielectric layer 95 and a first upper electrode 96. The first contact pad is of a stepped structure. The first contact pad 93 covers a top surface of the first bit line stack structure 92 and extends downwards to cover a top surface of the first storage contact structure 91. The first lower electrode 94 is disposed on a top surface of the first contact pad 93, and a bottom surface of the first lower electrode 94 is a planar surface. As shown in FIG. 2, the first lower electrode 94 is cylinder-shaped. In the related art, generally, in order to increase the capacity of a capacitor, the height of the first lower electrode 94 is increased by extending the first lower electrode 94 upwards, but the upward extending height of the first lower electrode 94 is limited by the thickness of a semiconductor device. It is known from the background art that the main research and development direction of the semiconductor device is to reduce the thickness thereof, but as the thickness of the semiconductor device decreases, it is difficult for the capacitor to maintain sufficient capacity.

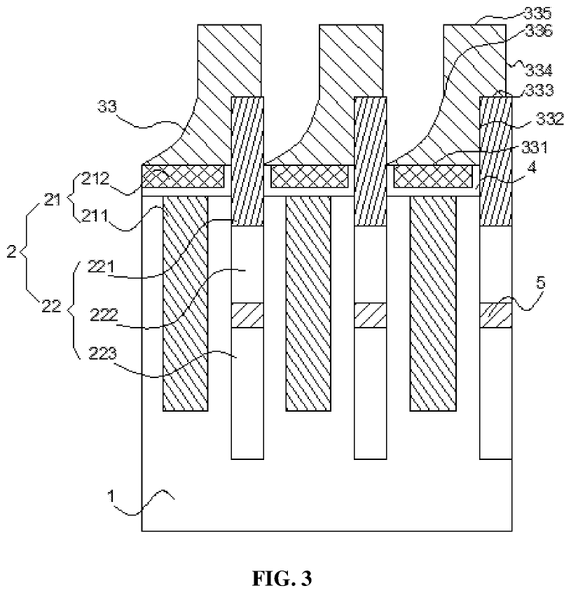

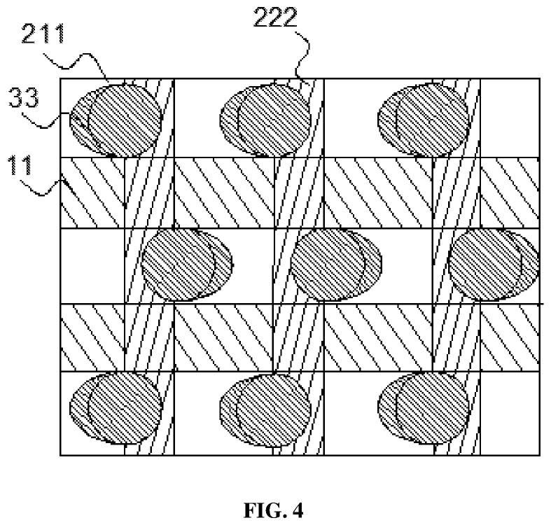

FIG. 3 illustrates a schematic cross-sectional view of a semiconductor structure according to an exemplary embodiment of the disclosure. FIG. 4 illustrates a top view of a semiconductor structure according to an exemplary embodiment of the disclosure. As shown in FIG. 3 and FIG. 4, the exemplary embodiment of the disclosure provides a semiconductor structure. The semiconductor structure includes a substrate 1, a support structure 2 and a capacitor structure which are stacked onto one another. The support structure 2 includes a bit line stack structure 22 and a storage contact structure 21. The bit line stack structure 22 and the storage contact structure 21 are disposed above the substrate 1, and the capacitor structure covers the bit line stack structure 22 and the storage contact structure 21.

Optionally, the substrate 1 includes one or more of the following semiconductor materials: silicon (Si), germanium (Ge), silicon germanium (SiGe), and silicon-on-insulator (SOI). Optionally, the substrate 1 includes a word line 11 extending in a first direction. Optionally, the word line 11 is embedded in the substrate 1. Optionally, the substrate includes a plurality of word lines 11, and the plurality of word lines 11 are spaced apart from each other. Optionally, the word line 11 includes one or more of the following conductive materials: polysilicon, tungsten, and metal silicide.

The support structure includes a plurality of bit line stack structures 22. The plurality of bit line stack structures 22 are disposed on a top surface of the substrate 1, and the plurality of bit line stack structures 22 are spaced apart from each other. The plurality of bit line stack structures 22 extend in a second direction, where the second direction intersects with the first direction. Optionally, the second direction is perpendicular to the first direction. The longitudinal cross section of each of the plurality of bit line stack structures 22 is rectangular. Each of the plurality of bit line stack structures 22 includes a bit line insulating layer 221, a bit line 222 and a bit line contact plug 223 which are sequentially stacked onto one another from top to bottom. Optionally, the bit line 222 includes one or more of the following conductive materials: tungsten, aluminum, copper, nickel, and cobalt. The bit line 222 is connected to the bit line contact plug 223 by a bit line adhesion layer 5. When the bit line 222 is in a direct contact with the bit line contact plug 223, the adhesion is poor, which affects the electrical performance of the bit line 222. The bit line 222 is connected to the bit line contact plug 223 by the bit line adhesion layer 5, which can improve the stability of the overall structure. Optionally, the bit line adhesion layer 5 includes silicon nitride or silicon oxynitride.

The storage contact structure 21 is disposed on the substrate 1. Optionally, the storage contact structure 21 is disposed between two of the plurality of bit line stack structures 22. Optionally, the storage contact structure 21 is disposed in intersecting gaps of the plurality of bit line stack structures 22 and the plurality of word lines 11. Optionally, the support structure includes a plurality of storage contact structures 21. A top surface of each of the plurality of storage contact structures 21 is lower than a top surface of each of the plurality of bit line stack structures 22. Optionally, each of the plurality of storage contact structures 21 includes a storage node plug 211 and a contact pad 212 disposed above the storage node plug 211. Optionally, the storage node plug 211 includes polysilicon. Optionally, the contact pad 212 includes tungsten oxide. Optionally, the longitudinal cross section of each of the plurality of storage contact structures 21 is T-shaped. Optionally, the contact pad 212 is connected to the storage node plug 211 by a pad adhesion layer 4. When the contact pad 212 is in direct contact with the storage node plug 211, the adhesion is poor. The contact pad is connected to the storage node plug 211 by the pad adhesion layer 4, which can improve the stability of the overall structure. Optionally, a top surface of the storage node plug 211 is higher than a bottom surface of the bit line insulating layer 221. A bottom surface of the storage node plug 211 is higher than a bottom surface of the bit line contact plug 223.

The capacitor structure is disposed on a top surface of the support structure 2, and the capacitor structure is a columnar capacitor or a cup-shaped capacitor. A method for preparing a cup-shaped capacitor includes the following operations. A lower electrode 33 is formed on a side wall of each of capacitor holes, and then a dielectric layer and an upper electrode are sequentially deposited on an outer side of the lower electrode 33. A method for preparing a columnar capacitor includes the following operations. A lower electrode 33 filling each of whole capacitor holes is formed, and then a dielectric layer and an upper electrode are sequentially deposited on an outer side of the lower electrode 33.

A part of a bottom surface of each of the lower electrodes 33 is in contact with the top surface of a respective one of the plurality of storage contact structures 21, and another part of the bottom surface of each of the lower electrodes 33 is in contact with the top surface of a respective one of the plurality of bit line stack structures 22. As shown in FIG. 3, optionally, the bit line stack structure 22 corresponding to each of the lower electrodes 33 is located on the right side of the storage contact structure 21. Optionally, each of the lower electrodes 33 is in contact with a side surface of a respective one of the plurality of bit line stack structures 22. Optionally, the contact area between each of the lower electrodes 33 and the top surface of a respective one of the plurality of storage contact structures 21 is greater than the contact area between each of the lower electrodes 33 and the top surface of a respective one of the plurality of bit line stack structures 22. The cross-sectional area of a lower part of each of the lower electrodes 33 is gradually increased from top to bottom, so that a part of the bottom surface of each of the lower electrodes 33 matches with the top surface of a respective one of the plurality of storage contact structures 21, thereby increasing the contact area between each of the lower electrodes 33 and the respective one of the plurality of storage contact structures 21. In some specific implementation modes, the bottom surface of each of the lower electrodes 33 is stepped, and the area of the top surface of each of the lower electrodes 33 is less than the area of the bottom surface of each of the lower electrodes 33. The longitudinal cross section of each of the lower electrodes 33 is defined by a first side 331, a second side 332, a third side 333, a fourth side 334, a fifth side 335 and a sixth side 336 which are adjacent to each other in sequence. The first side 331 is in contact with the top surface of the respective one of the plurality of storage contact structures 21. The second side 332 is in contact with the side surface of the respective one of the plurality of bit line stack structures 22. The third side 333 is in contact with the top surface of the respective one of the plurality of bit line stack structures 22. The fourth side 334 is disposed in the vertical direction. The fifth side 335 is disposed in the horizontal direction. An upper part of the sixth side 336 is in the form of a straight line disposed in the vertical direction, a lower part of the sixth side 336 is in the form of an arc line, and the arc side surface increases the contact area between each of the lower electrodes 33 and a respective one of capacitance dielectric layers (not shown in the figures). Optionally, each of the lower electrodes 33 includes one or more of the following materials: titanium (Ti), tungsten (W), and tungsten nitride (WN). Compared with a columnar lower electrode in the related art, each of the lower electrodes 33 provided by the exemplary embodiment of the disclosure is provided with the stepped bottom surface, so that the stability of the overall structure is higher, and the risk of collapse of the capacitor can be reduced.

In some related arts, the top surface of the contact pad 212 is generally higher than the top surface of the bit line insulating layer 221. Since the lower electrode 33 is disposed on the top surface of the contact pad 212, the height of the top surface of the contact pad 212 limits the height of the lower electrode 33 without changing the semiconductor device. In the exemplary embodiment of the disclosure, the height of the top surface of the contact pad 212 is reduced by removing part of the contact pad 212. Then the lower electrode 33 is enabled to extend towards the contact pad 212, so that the height of the lower electrode 33 can be increased without increasing the thickness of the semiconductor device, thereby further increasing the capacity of the capacitor.

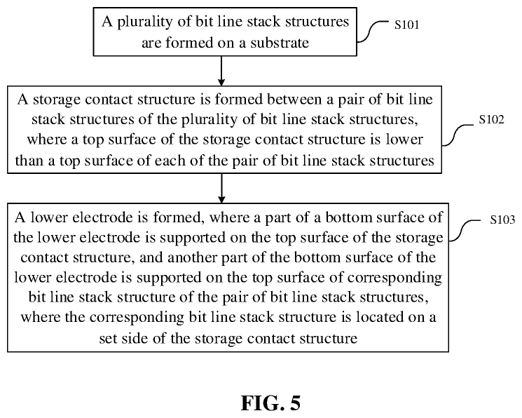

FIG. 5 illustrates a flowchart of a method for preparing a semiconductor structure according to an embodiment of the disclosure. As shown in FIG. 5, the exemplary embodiment of the disclosure provides a method for preparing a semiconductor structure, which includes the following operations.

At S101, a plurality of bit line stack structures 22 are formed on a substrate 1. In some specific implementation modes, the operation that the plurality of bit line stack structures 22 are formed on the substrate 1 includes the following operations. A plurality of bit line contact plugs 223 are formed above the substrate 1, a plurality of bit lines 222 are formed above the plurality of bit line contact plugs 223, and a plurality of bit line insulating layers 221 are formed above the plurality of bit lines 222. In some specific implementation modes, the substrate 1 includes a plurality of active areas, etching processing is performed along the central parts of the plurality of active areas to form a plurality of first grooves, and the plurality of first grooves are filled to form the plurality of bit line stack structures 22.

At S102, a storage contact structure 21 is formed between a pair of bit line stack structures 22 of the plurality of bit line stack structures 22, where a top surface of the storage contact structure 21 is lower than a top surface of each of the pair of bit line stack structures 22. In some specific implementation modes, a second groove is formed between a pair of bit line stack structures 22 by etching, and the second groove is filled to form the storage contact structure 21. In some specific implementation modes, the operation that a storage contact structure 21 is formed between a pair of bit line stack structures 22 of the plurality of bit line stack structures 22 includes the following operations. A storage node plug 211 is formed above the substrate 1, and a contact pad 212 is formed above the storage node plug 211. Optionally, the storage node plug 211 includes one or more of the following materials: polysilicon, titanium nitride, titanium, and metal nitride.

At S103, a lower electrode is formed, where a part of a bottom surface of the lower electrode 33 is supported on the top surface of the storage contact structure 21, and another part of the bottom surface of the lower electrode 33 is supported on the top surface of a respective one of the pair of bit line stack structures 22.

In some related arts, the top surface of the contact pad 212 is generally higher than the top surface of the bit line insulating layer 221. Since the lower electrode 33 is disposed on the top surface of the contact pad 212, the height of the top surface of the contact pad 212 limits the height of the lower electrode 33 without changing a semiconductor device. In the exemplary embodiment of the disclosure, the height of the top surface of the contact pad 212 is reduced by removing part of the contact pad 212. Then the lower electrode 33 is enabled to extend towards the contact pad 212, so that the height of the lower electrode 33 can be increased without increasing the thickness of the semiconductor device, thereby further increasing the capacity of the capacitor.

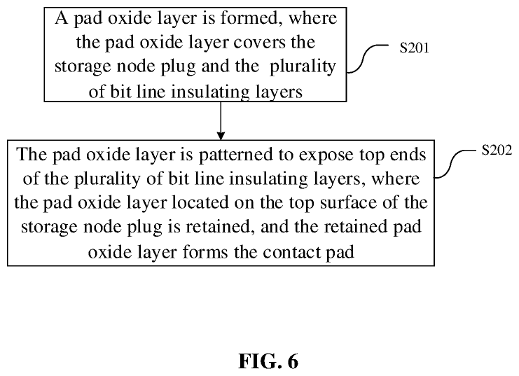

FIG. 6 illustrates a flowchart of a method for preparing a contact pad 212 according to an exemplary embodiment of the disclosure. As shown in FIG. 6, the method for preparing the contact pad 212 includes the following operations.

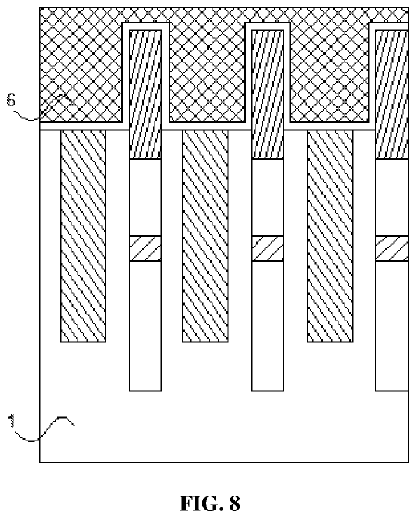

At S201, a pad oxide layer 6 is formed, where the pad oxide layer 6 covers the storage node plug 211 and the plurality of bit line insulating layer 221. FIG. 8 illustrates a schematic diagram when S201 is performed according to a method for preparing a contact pad 212 provided by an embodiment as shown in FIG. 6. As shown in FIG. 8, the pad oxide layer 6 is formed on the top surface of the storage node plug 211, top surfaces of the plurality of bit line insulating layers 221, and exposed side surfaces of the plurality of bit line insulating layers 221. Optionally, the pad oxide layer 6 includes tungsten oxide.

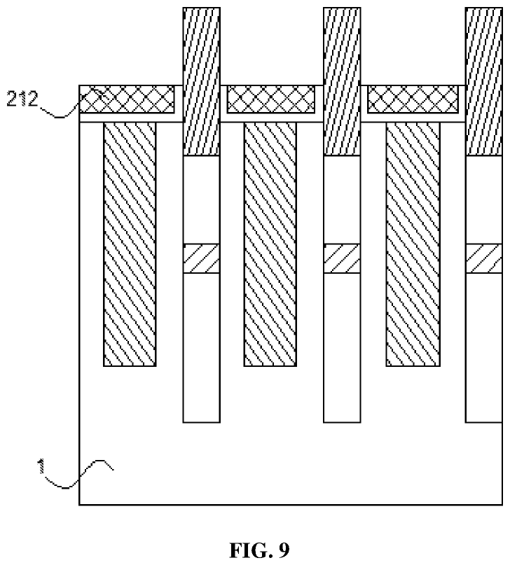

At S202, the pad oxide layer 6 is patterned to expose top ends of the plurality of bit line insulating layers 221, where the pad oxide layer 6 located on a top surface of the storage node plug 211 is retained, and the retained pad oxide layer 6 forms the contact pad 212. FIG. 9 illustrates a schematic diagram when S202 is performed according to a method for preparing a contact pad 212 provided by an embodiment as shown in FIG. 6. As shown in FIG. 9, the pad oxide layer 6 located above the plurality of bit line insulating layers 221 is removed by etching, and a part of the pad oxide layer 6 located above the storage node plug 211 is removed by etching. In some specific implementation modes, patterning includes photoresist coating, exposure, development, etching, and stripping.

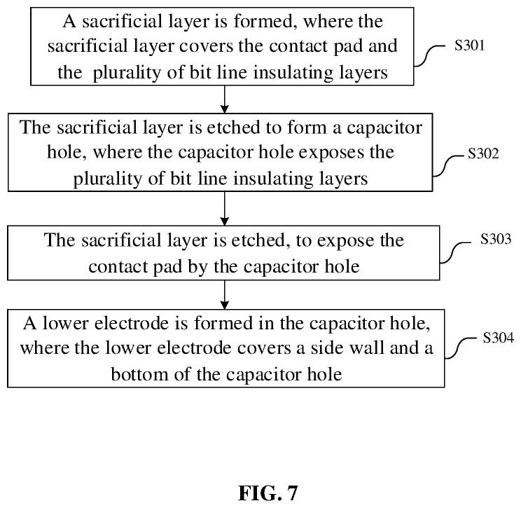

FIG. 7 illustrates a flowchart of a method for preparing a lower electrode 33 according to an exemplary embodiment of the disclosure. As shown in FIG. 7, the method for preparing the lower electrode 33 includes the following operations.

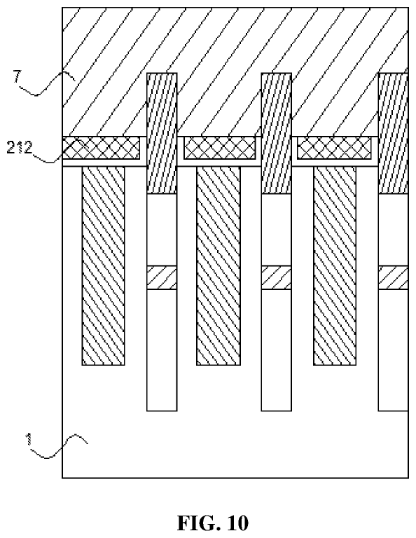

At S301, a sacrificial layer 7 is formed, where the sacrificial layer 7 covers the contact pad 212 and the plurality of bit line insulating layers 221. FIG. 10 illustrates a schematic diagram when S301 is performed according to a method for preparing a lower electrode 33 provided by an embodiment as shown in FIG. 7. As shown in FIG. 10, a sacrificial layer 7 is formed, where the sacrificial layer 7 covers a top surface of the contact pad 212, top surfaces of the plurality of bit line insulating layers 221, and exposed side surfaces of the plurality of bit line insulating layers 221. The sacrificial layer 7 is an insulation material.

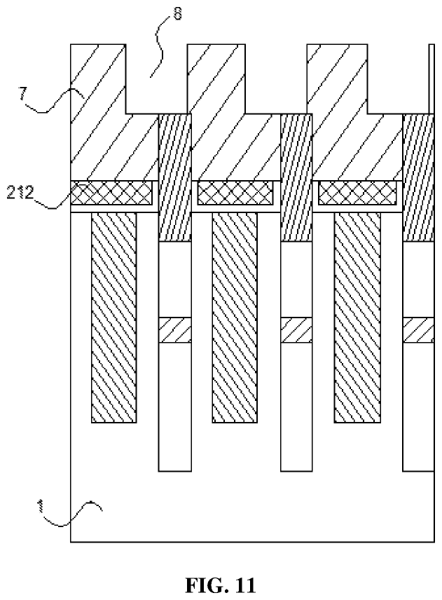

At S302, the sacrificial layer 7 is etched to form a capacitor hole 8, where the capacitor hole 8 exposes the plurality of bit line insulating layers 221. FIG. 11 illustrates a schematic diagram when S302 is performed according to a method for preparing a lower electrode 33 provided by an embodiment as shown in FIG. 7. Optionally, the capacitor hole 8 is cylinder-shaped, and the capacitor hole 8 exposes the top surface of the bit line insulating layer 221.

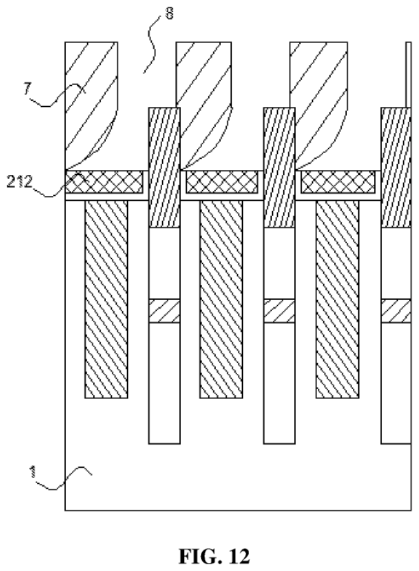

At S303, the sacrificial layer 7 is etched, to expose the contact pad 212 by the capacitor hole 8. FIG. 12 illustrates a schematic diagram when S303 is performed according to a method for preparing a lower electrode 33 provided by an embodiment as shown in FIG. 7. As shown in FIG. 12, the sacrificial layer 7 located on the bottom surface of the capacitor hole 8 is etched, where the bottom surface of the capacitor hole 8 extends towards the contact pad 212 until the contact pad 212 is exposed.

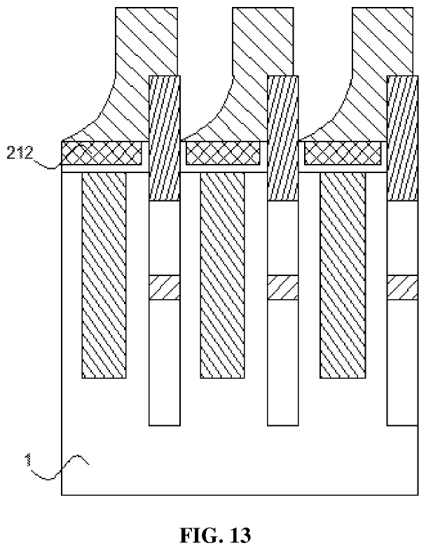

At S304, a lower electrode 33 is formed in the capacitor hole 8, where the lower electrode 33 covers a side wall and a bottom of the capacitor hole 8. The capacitor hole 8 is L-shaped. FIG. 13 illustrates a schematic diagram when S304 is performed according to a method for preparing a lower electrode 33 provided by an embodiment as shown in FIG. 7. As shown in FIG. 13, a conductive material is deposited in the capacitor hole 8 to form the lower electrode 33. Optionally, the lower electrode 33 includes one or more of the following materials: titanium (Ti), tungsten (W), nickel (Ni), cobalt (Co), and metal nitride.

1. A semiconductor structure, comprising:
a plurality of bit line stack structures, wherein the plurality of bit line stack structures are disposed on a substrate;
a plurality of storage contact structures, wherein each of the plurality of storage contact structures is disposed between a pair of bit line stack structures of the plurality of bit line stack structures, and a top surface of each of the plurality of storage contact structures is lower than a top surface of each of the plurality of bit line stack structures; and
a plurality of capacitor structures, wherein a part of a bottom surface of a lower electrode of each of the plurality of capacitor structures is supported on the top surface of a respective one of the plurality of storage contact structures, and another part of the bottom surface of the lower electrode is supported on the top surface of a respective one of the plurality of bit line stack structures.

2. The semiconductor structure of claim 1, wherein each of the plurality of storage contact structures comprises a storage node plug and a contact pad disposed above the storage node plug;
wherein each of the plurality of bit line stack structures comprises a bit line insulating layer, a bit line and a bit line contact plug which are sequentially stacked onto one another from top to bottom.

3. The semiconductor structure of claim 2, wherein the contact pad is connected to the storage node plug by a pad adhesion layer.

4. The semiconductor structure of claim 2, wherein the bit line is connected to the bit line contact plug by a bit line adhesion layer.

5. The semiconductor structure of claim 2, wherein a top surface of the storage node plug is higher than a bottom surface of the bit line insulating layer;
wherein a bottom surface of the storage node plug is higher than a bottom surface of the bit line contact plug.

6. The semiconductor structure of claim 1, wherein an area of a top surface of the lower electrode is less than an area of the bottom surface of the lower electrode.

7. The semiconductor structure of claim 1, wherein a cross section of a lower part of the lower electrode is gradually increased from top to bottom.

8. The semiconductor structure of claim 1, wherein a longitudinal cross section of each of the plurality of storage contact structures is T-shaped.

9. The semiconductor structure of claim 1, wherein each of the plurality of capacitor structures is a columnar capacitor or a cup-shaped capacitor.

10. The semiconductor structure of claim 1, wherein a contact area of the lower electrode and the top surface of the respective one of the plurality of storage contact structures is greater than a contact area of the lower electrode and the top surface of the respective one of the plurality of bit line stack structures.

11. A method for preparing a semiconductor structure, comprising:
forming a plurality of bit line stack structures on a substrate;
forming a storage contact structure between a pair of bit line stack structures of the plurality of bit line stack structures, wherein a top surface of the storage contact structure is lower than a top surface of each of the plurality of bit line stack structures; and
forming a lower electrode, wherein a part of a bottom surface of the lower electrode is supported on the top surface of the storage contact structure, and another part of the bottom surface of the lower electrode is supported on the top surface of a respective one of the pair of bit line stack structures.

12. The method for preparing the semiconductor structure of claim 11, wherein forming the plurality of bit line stack structures on the substrate comprises:
forming a plurality of bit line contact plugs above the substrate;
forming a plurality of bit lines above the plurality of bit line contact plugs; and
forming a plurality of bit line insulating layers above the plurality of bit lines;
wherein forming the storage contact structure between the pair of bit line stack structures of the plurality of bit line stack structures comprises:
forming a storage node plug above the substrate; and
forming a contact pad above the storage node plug.

13. The method for preparing the semiconductor structure of claim 12, wherein forming the contact pad above the storage node plug comprises:
forming a pad oxide layer, wherein the pad oxide layer covers the storage node plug and the plurality of bit line insulating layers; and
patterning the pad oxide layer to expose top ends of the plurality of bit line insulating layers, wherein the pad oxide layer located on a top surface of the storage node plug is retained, and retained pad oxide layer forms the contact pad.

14. The method for preparing the semiconductor structure of claim 12, wherein the plurality of bit line stack structures and the storage contact structure form a support structure, and the lower electrode is located on a top surface of the support structure, and wherein forming the lower electrode on the top surface of the support structure comprises:
forming a sacrificial layer, wherein the sacrificial layer covers the contact pad and the plurality of bit line insulating layers;
etching the sacrificial layer to form a capacitor hole, wherein the capacitor hole exposes the plurality of bit line insulating layers;
etching the sacrificial layer, to expose the contact pad by the capacitor hole; and
forming the lower electrode in the capacitor hole, wherein the lower electrode covers a side wall and a bottom of the capacitor hole.

15. The method for preparing the semiconductor structure of claim 14, wherein the capacitor hole is L-shaped.

16. The method for preparing the semiconductor structure of claim 12, wherein each of the plurality of bit lines comprises one or more of the following materials: tungsten, aluminum, copper, nickel, and cobalt.
